(19) United States
(12) Patent Application Publication
(10) Pub. No.: US 2016/0043252 A1
(43) Pub. Date: Feb. 11, 2016

(54) SOLAR CELL, ELECTRONIC DEVICE, AND MANUFACTURING METHOD OF SOLAR CELL

(71) Applicant: SEIKO EPSON CORPORATION, Tokyo (JP)

(72) Inventor: Daisuke NAGANO, Matsumoto-shi (JP)

(21) Appl. No.: 14/813,764

(22) Filed: Jul. 30, 2015

(30) Foreign Application Priority Data
Aug. 6, 2014 (JP) 2014-160183

(51) Int. Cl. H01L 31/0352; G04C 10/02; H01L 31/18

(52) U.S. Cl. CPC H01L 31/035281; H01L 31/18; G04C 10/02

(57) ABSTRACT

A power generating film is disposed on a first surface of a substrate, a transparent conductive film is disposed on the power generating film in an overlapping manner, and a first front resist film and a first back resist film are disposed on the transparent conductive film and a second surface on a side opposite to the first surface, the first back resist film is patterned into a predetermined shape, and the substrate is formed into a predetermined shape by spraying an etching liquid onto the substrate from the second surface side.

### BACKGROUND

1. Technical Field

This application claims a priority to Japanese Patent Application No. 2014-160183 filed on Aug. 6, 2014 which is hereby expressly incorporated by reference in its entirety.

Several aspects of the present invention relate to a solar cell, an electronic device, and a manufacturing method of a solar cell.

2. Related Art

A solar cell which receives light such as solar light and generates power has been widely used. In the solar cell, a power generating film and a transparent conductive film are disposed on the substrate. Then, a cutting method of the substrate is disposed in JP-A-2010-245255. According to this, in a cutting device, a blade in the shape of a triangular prism oscillates in one direction such that the substrate is cut at a tip end of the blade.

According to this method, the power generating film and the transparent conductive film are able to be cut along a straight line without concavities and convexities. However, when the power generating film and the transparent conductive film are cut along a curved line, the oscillation direction of the blade has to be complicatedly controlled. Accordingly, it is difficult to form the solar cell with high productivity.

In a case where the solar cell is formed by using an etching method, the solar cell is able to be easily formed even when a curved line is included. Then, the accuracy of the shape becomes more excellent as the accuracy of a mask is excellent. In the etching method, the etching is performed by spraying an etching liquid onto the substrate, and thus it is possible to manufacture the solar cell with high productivity compared to the method of performing the cutting by the blade as with the method disclosed in JP-A-2010-245255. Accordingly, the shape of the solar cell is formed by using the etching method, and thus a solar cell having a complicate shape is also able to be manufactured with high position accuracy and high productivity.

The substrate, the power generating film, and the transparent conductive film are formed of different materials, and etching liquids corresponding to the respective materials are used. When the outer shape of the solar cell is formed, first, the mask for etching the transparent conductive film is disposed and the transparent conductive film is etched. Next, the power generating film is etched. Subsequently, in the substrate, the mask is disposed on a surface on a side opposite to a surface on which the transparent conductive film is disposed, and thus the substrate is etched from both surfaces. According to this method, the substrate, the power generating film, and the transparent conductive film are etched, and thus the outer shape of the solar cell is able to be formed.

The power generating film is not able to be etched by using the etching liquid for etching the substrate. Therefore, in a method of spraying the etching liquid onto the substrate from the both surfaces of a first surface and a second surface, first, a resist film is disposed on the first surface and the second surface, and is patterned. The power generating film is etched, and is patterned into a predetermined shape. Next, the etching liquid is sprayed from the both surfaces of the substrate. Accordingly, it is necessary to perform the etching twice by changing the etching liquid. Therefore, a manufacturing method of a solar cell which is able to be manufactured with higher productivity is demanded.

### SUMMARY

An advantage of some aspects of the invention is to solve the problems described above, and the invention can be implemented as the following forms or application examples.

### Application Example 1

This application example is directed to a manufacturing method of a solar cell including disposing a power generating film on a first surface of a substrate, disposing a first resist film on the first surface side and a second surface on a side opposite to the first surface, patterning the first resist film into a predetermined shape, and forming the substrate into a predetermined shape by spraying an etching liquid onto the substrate from the second surface side.

In this application example, the power generating film is disposed on the first surface of the substrate. The first resist film is disposed on the first surface of the substrate and the second surface on the side opposite to the first surface, and the first resist film is patterned into a predetermined shape. Then, the etching liquid is sprayed onto the substrate from the second surface side by using the first resist film as a mask, and thus the substrate is formed into a predetermined shape.

The substrate is able to be etched by using the etching liquid, and the power generating film is not able to be dissolved by the etching liquid. When the substrate is etched from the second surface side, the substrate is removed into a predetermined shape in a portion where the first resist film does not exist, and thus becomes thin. Then, the power generating film is a thin film, and thus is removed by being blown off due to the spray of the etching liquid. Accordingly, the power generating film is able to be formed into the same shape as that of the etched substrate. That is, the power generating film and the substrate are etched by performing the etching once.

In a method of spraying the etching liquid onto the substrate from the both surfaces of the first surface and the second surface, first, the power generating film is etched, and thus is patterned into a predetermined shape. Next, the first resist film is disposed on the second surface and is patterned. Subsequently, the substrate is etched by spraying the etching liquid onto the substrate from the both surfaces. Accordingly, the power generating film and the substrate are etched by performing the etching twice. In a method of spraying the etching liquid only from the second surface, the etching is performed once, and thus it is possible to form a solar cell with high productivity compared to the method where the etching is performed twice.

### Application Example 2

This application example is directed to the manufacturing method of a solar cell according to the application example described above, which further includes disposing a transparent conductive film on the power generating film in an overlapping manner before disposing the first resist film, disposing the first resist film on the transparent conductive film, etching the transparent conductive film after the first resist film is patterned, and disposing a second resist film by covering a side surface of the transparent conductive film.

In this application example, the transparent conductive film is patterned before etching the substrate. Then, the transparent conductive film is covered with the first resist film, and the side surface of the transparent conductive film is covered with the second resist film. Accordingly, the substrate is etched into the shape where the transparent conductive film is covered with the first resist film and the second resist film. As a result thereof, it is possible to prevent the transparent conductive film from being corroded by the etching liquid.

### Application Example 3

This application example is directed to the manufacturing method of a solar cell according to the application example described above, wherein, when the etching liquid is sprayed onto the substrate, the second surface is directed towards a gravitational acceleration direction.

In this application example, the second surface of the substrate is directed towards the gravitational acceleration direction, and then the etching liquid is sprayed onto the second surface. The etching liquid which has reached the second surface reacts with the substrate, and thus includes the material of the substrate. Then, the etching liquid positioned on the second surface is separated from the second surface due to the action of a gravitational force.

Accordingly, in the second surface of the substrate, the etching liquid including the material of the substrate is removed and at the same time the etching liquid excluding the material of the substrate is supplied. As a result thereof, it is possible to efficiently etch the substrate.

### Application Example 4

This application example is directed to a solar cell, in which a substrate includes a first surface and a second surface facing the first surface, a power generating film is disposed on the first surface of the substrate, a side surface of the substrate is inclined with respect to the first surface, and the first surface protrudes with respect to the second surface.

In this application example, the substrate includes the first surface and the second surface, the first surface and the second surface are arranged to face each other. Then, the power generating film is disposed on the first surface of the substrate. The side surface of the substrate is inclined with respect to the first surface. Then, the first surface protrudes with respect to the second surface. The side surface of the substrate is inclined with respect to the first surface, and thus the substrate is formed by spraying an etching liquid thereto. Then, the first surface on which the power generating film is disposed protrudes from the second surface, and thus a resist film is disposed on the second surface and the etching liquid is sprayed from the second surface side. At this time, the etching liquid is sprayed only from the second surface. Accordingly, the solar cell of this application example is patterned once, and thus has no position shift in the patterning. In addition, the substrate and the power generating film are etched once, and thus it is possible to manufacture the solar cell with high productivity compared to the method where the etching is performed twice separately.

### Application Example 5

This application example is directed to an electronic device including a solar cell. In the solar cell, a substrate includes a first surface and a second surface facing the first surface, and a power generating film is disposed on the first surface of the substrate, a side surface of the substrate is inclined with respect to the first surface, and the first surface protrudes with respect to the second surface.

In this application example, the electronic device includes the solar cell. The substrate of the solar cell includes the first surface and the second surface, and the first surface and the second surface are arranged to face each other. Then, the power generating film is disposed on the first surface of the substrate. The side surface of the substrate is inclined with respect to the first surface. Then, the first surface protrudes with respect to the second surface. The side surface of the substrate is inclined with respect to the first surface, and thus the substrate is formed by spraying an etching liquid thereto. Then, the first surface on which the power generating film is disposed protrudes from the second surface, and thus a resist film is disposed on the second surface and the etching liquid is sprayed from the second surface side. At this time, the etching liquid is sprayed only from the second surface.

Accordingly, the solar cell of this application example is patterned once, and thus has no position shift in the patterning, and is formed with high shape accuracy. In addition, the substrate and the power generating film are etched once, and thus it is possible to manufacture the solar cell with high productivity compared to the method where the etching is performed twice separately. As a result thereof, it is possible to manufacture the electronic device including the solar cell which is formed with high shape accuracy and high productivity.

### BRIEF DESCRIPTION OF THE DRAWINGS

The invention will be described with reference to the accompanying drawings, wherein like numbers reference like elements.

FIG. 1A is a schematic perspective view illustrating a structure of a solar cell according to a first embodiment, FIG. 1B is a circuit diagram of the solar cell according to the first embodiment, and FIG. 1C is a schematic side sectional view of main parts illustrating a structure of a power generating film according to the first embodiment.

FIG. 2A is a schematic plan view illustrating a structure of the power generating film and a transparent conductive film, and FIG. 2B is a schematic side sectional view illustrating a structure of a substrate, the power generating film, and the transparent conductive film.

FIG. 3 is a flowchart of a manufacturing method of a solar cell.

FIGS. 4A to 4D are schematic views for illustrating the manufacturing method of a solar cell.

FIGS. 5A to 5C are schematic views for illustrating the manufacturing method of a solar cell.

FIGS. 6A to 6C are schematic views for illustrating the manufacturing method of a solar cell.

FIGS. 7A to 7D are schematic views for illustrating the manufacturing method of a solar cell.

FIGS. 8A to 8D are schematic views for illustrating the manufacturing method of a solar cell.

FIGS. 9A to 9C are schematic views for illustrating the manufacturing method of a solar cell.

FIG. 10A is a schematic side view illustrating a structure of a timepiece according to a second embodiment, and FIG. 10B is a schematic plan view illustrating a structure of a solar cell according to the second embodiment.

FIG. 11 is a schematic plan view of a solar cell-attached substrate.

### DESCRIPTION OF EXEMPLARY EMBODIMENTS

In this embodiment, discriminative examples of a solar cell and a manufacturing method of a solar cell will be described with reference to the drawings. Furthermore, each member in each drawing is a recognizable size, and thus the scale size is different for each member.

### First Embodiment

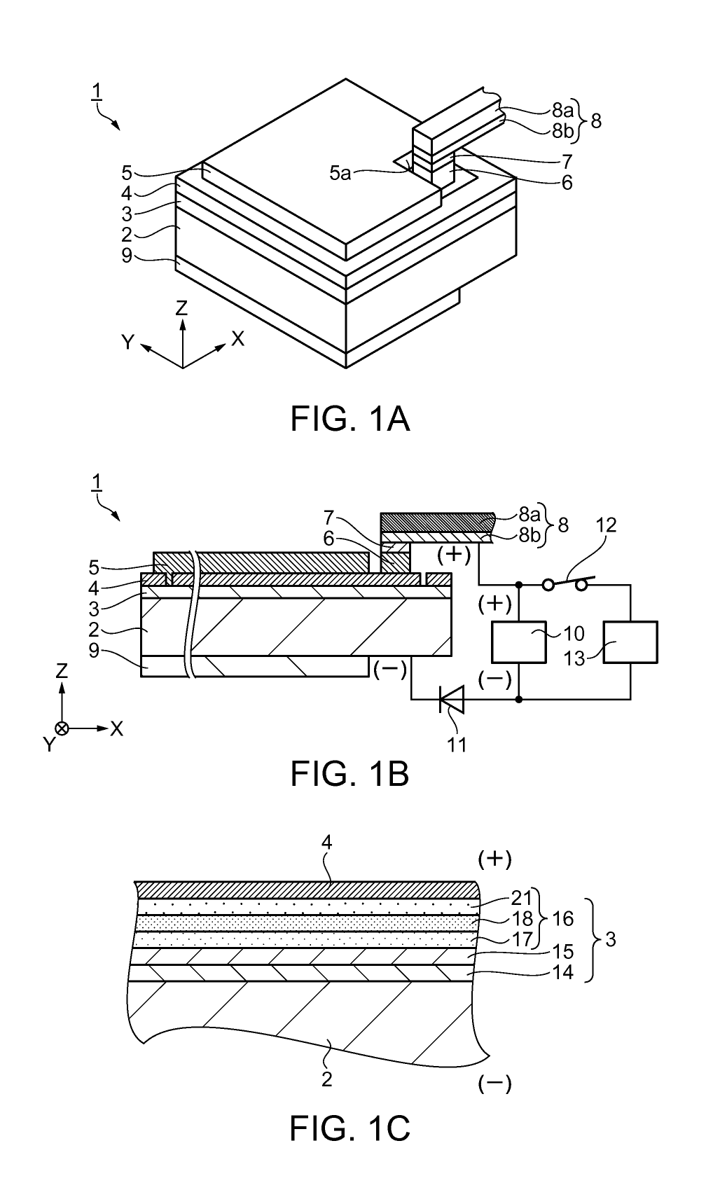

A solar cell according to a first embodiment will be described with reference to FIGS. 1A to 9C. FIG. 1A is a schematic perspective view illustrating a structure of a solar cell. As illustrated in FIG. 1A, a solar cell 1 includes a quadrangular substrate 2. The substrate 2 may be a plate member having conductivity, and as the substrate 2, various metal plates are able to be used. In this embodiment, for example, a stainless steel plate is used as the substrate 2. The stainless steel plate has excellent corrosion resistance, and thus is rarely oxidized in an environment used in a manufacturing process. A thickness direction of the substrate 2 is a Z direction, and directions in which two orthogonal sides of the substrate 2 extend are an X direction and a Y direction.

A power generating film 3, a transparent conductive film 4, and a first insulating film 5 are disposed on the surface of the substrate 2 on a +Z direction side in this order in an overlapping manner. The power generating film 3 is a film having an electromotive force which receives light and allows electric current to flow. The transparent conductive film 4 is a film having light transmissive properties and conductivity. The type of the transparent conductive film 4 is not particularly limited, and as the transparent conductive film 4, for example, IGO (Indium-Gallium Oxide), ITO (Indium Tin Oxide), and ICO (Indium-Cerium Oxide) are able to be used. In this embodiment, for example, ITO is adopted in the transparent conductive film 4. The first insulating film 5 is a film which protects and electrically insulates the transparent conductive film 4. The type of the first insulating film 5 is not particularly limited, and as the first insulating film 5, for example, a resin film of an acrylic resin or the like is able to be used.

The first insulating film 5 includes a cut-out portion 5a which is cut out such that a corner in the X direction and a −Y direction is in the shape of a quadrangle. Accordingly, in the cut-out portion 5a, the transparent conductive film 4 is exposed. Then, in the cut-out portion 5a, a conductive paste 6 and an anisotropic conductive film 7 are disposed on the transparent conductive film 4 in an overlapping manner, and a wiring member 8 is disposed on the anisotropic conductive film 7.

The conductive paste 6 is obtained by dispersing conductive particles in a resin material, and is used by solidifying the resin material. The material of the conductive particles of the conductive paste is not particularly limited, and as the material, carbon particles referred to as carbon black in addition to metal such as silver, and copper, and the like are able to be used. In this embodiment, for example, the carbon particles are used in the material of the conductive particles of the conductive paste.

The anisotropic conductive film 7 is an anisotropic conductive film. The anisotropic conductive film 7 is obtained by dispersing conductive particles in an adhesive material formed of a resin material, and is used by solidifying the resin material. The conductive particles of the anisotropic conductive film 7 are not particularly limited, and as the conductive particles, for example, a spherical body having a diameter of 3 μm to 5 μm in which a nickel layer, and a gold plated layer are stacked on a spherical body of a resin such as a polystyrene from the inner side is able to be used. In addition, metal particles are able to be used.

In the wiring member 8, a metal film 8b is disposed on a flexible substrate 8a, and the metal film 8b is connected to the anisotropic conductive film 7. The flexible substrate 8a is a film-like insulating body, and as the flexible substrate 8a, a polyimide film referred to as a coverlay or a photo-solder resist film, a polyethylene terephthalate resin (PET), and the like are able to be used. The metal film 8b is a metal foil such as a copper foil, and is adhered to the flexible substrate 8a. In addition, a conductive film which is obtained by solidifying a carbon paste, a silver paste, or the like is able to be used in the metal film 8b.

A second insulating film 9 is disposed on the surface of the substrate 2 on a −Z direction side. The second insulating film 9 is not particularly limited insofar as the second insulating film 9 has insulating properties, and as the second insulating film 9, a resin material is able to be used. In this embodiment, for example, a polyester film is used as the second insulating film 9.

The thickness of each member is not particularly limited, and in this embodiment, for example, each member has the following thickness. The thickness of the substrate 2 is 50 μm to 200 μm, and the thickness of the power generating film 3 is 300 nm to 700 nm. The thickness of the transparent conductive film 4 is 40 nm to 100 nm.

FIG. 1B is a circuit diagram of the solar cell. As illustrated in FIG. 1B, in the solar cell 1, the wiring member 8 is a (+) electrode and the substrate 2 is a (−) electrode. The wiring member 8 is connected to a (+) electrode of a storage cell 10. The substrate 2 is connected to a (−) electrode of the storage cell 10 through a backward flow prevention diode 11. The backward flow prevention diode 11 is not particularly limited, and in this embodiment, as the backward flow prevention diode 11, for example, a schottky barrier diode is used.

The (+) electrode of the storage cell 10 is connected to a load circuit 13 through a switch 12, and the (−) electrode of the storage cell 10 is connected to the load circuit 13. The circuit is a circuit which energizes the load circuit 13 at the time of closing the switch 12.

FIG. 1C is a schematic side sectional view of main parts illustrating the structure of the power generating film 3. As illustrated in FIG. 1C, the power generating film 3 has a structure in which an aluminum layer 14 (an Al layer), a zinc oxide layer 15 (a ZnO layer), and a semiconductor layer 16 are laminated in this order from the substrate 2 side. Light is incident on the solar cell 1 from the transparent conductive film 4 side (a +Z side). The transparent conductive film 4 functions as a positive electrode. The substrate 2 functions as a negative electrode.

The aluminum layer 14 includes concavities and convexities on the surface thereof, and is a layer on which light which has transmitted the semiconductor layer 16 and the zinc oxide layer 15 among the light incident from the transparent conductive film 4 side is scattered and reflected. The zinc oxide layer 15 is a layer of adjusting the refractive index of the light between the semiconductor layer 16 and the aluminum layer 14.

The semiconductor layer 16 is not particularly limited, and in this embodiment, the semiconductor layer 16, for example, is a multi-junction type power generating layer having a 3-layer structure. The structure is referred to as a triple junction structure. The semiconductor layer 16 has a structure in which a first amorphous silicon germanium layer 17, a second amorphous silicon germanium layer 18, and an amorphous silicon layer 21 are laminated in this order from the zinc oxide layer 15 side.

The first amorphous silicon germanium layer 17 and the second amorphous silicon germanium layer 18 are formed by doping amorphous silicon with germanium. The amount of germanium doped on the first amorphous silicon germanium layer 17 is different from the amount of germanium doped on the second amorphous silicon germanium layer 18. The doping amount of the first amorphous silicon germanium layer 17 is greater than the doping amount of the second amorphous silicon germanium layer 18. Each of the first amorphous silicon germanium layer 17, the second amorphous silicon germanium layer 18, and the amorphous silicon layer 21 is set to have a different absorption wavelength region.

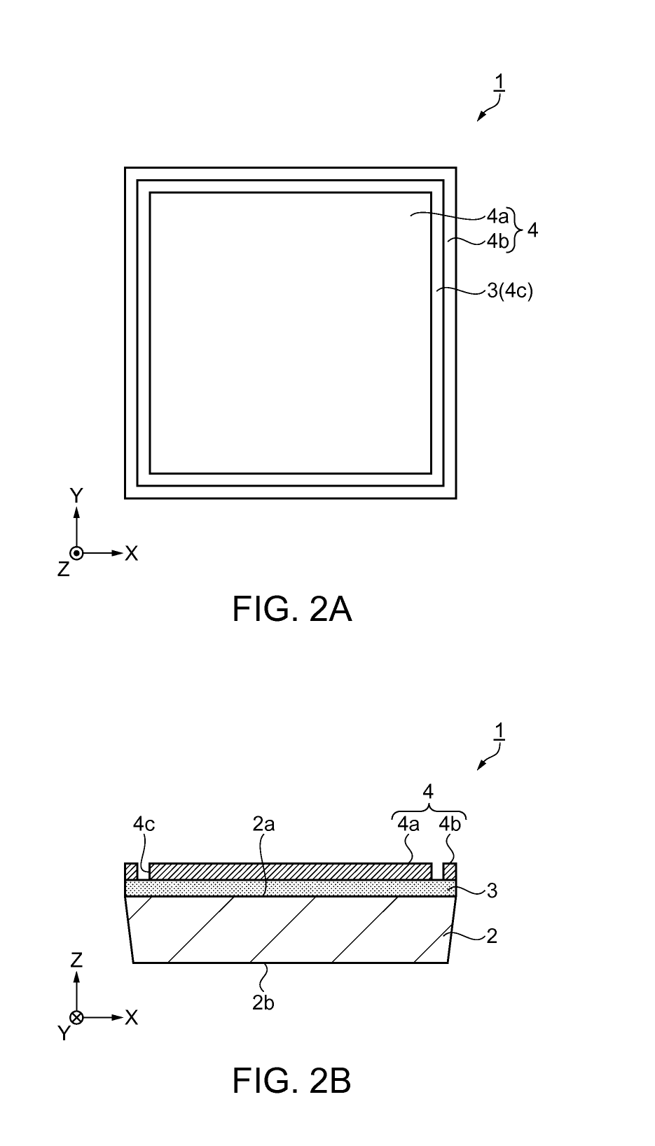

FIG. 2A is a schematic plan view illustrating the structure of the power generating film and the transparent conductive film. FIG. 2B is a schematic side sectional view illustrating the structure of the substrate, the power generating film, and the transparent conductive film. As illustrated in FIGS. 2A and 2B, the transparent conductive film includes a quadrangular effective region 4a which is positioned in the center. A groove portion 4c is disposed around the effective region 4a, and the power generating film 3 is exposed in the groove portion 4c. An ineffective region 4b is disposed around the groove portion 4c. Then, the outer shape of the ineffective region 4b, the outer shape of the power generating film 3, and the outer shape of the substrate 2 are identical to each other.

The effective region 4a functions as a (+) electrode of the solar cell 1. A part of the ineffective region 4b is able to be in contact with the substrate 2, and the potential of the ineffective region 4b is identical to that of the substrate 2 or is a floating potential. The width of the groove portion 4c and the ineffective region 4b is not particularly limited, and in this embodiment, for example, the width of the groove portion 4c is 50 μm to 200 μm, and the width of the ineffective region 4b is 100 μm to 600 μm.

In the substrate 2, a surface on which the power generating film 3 is disposed is a first surface 2a, and a surface on which the second insulating film 9 is disposed is a second surface 2b. A side surface of the substrate 2 is inclined with respect to the first surface 2a. Then, the first surface 2a protrudes with respect to the second surface 2b. In a manufacturing step of the solar cell 1, an etching liquid is sprayed from the second surface 2b side, and thus the shape of the substrate 2 is formed. For this reason, the substrate 2 is formed into the shape where the second surface 2b side is more etched than the first surface 2a side.

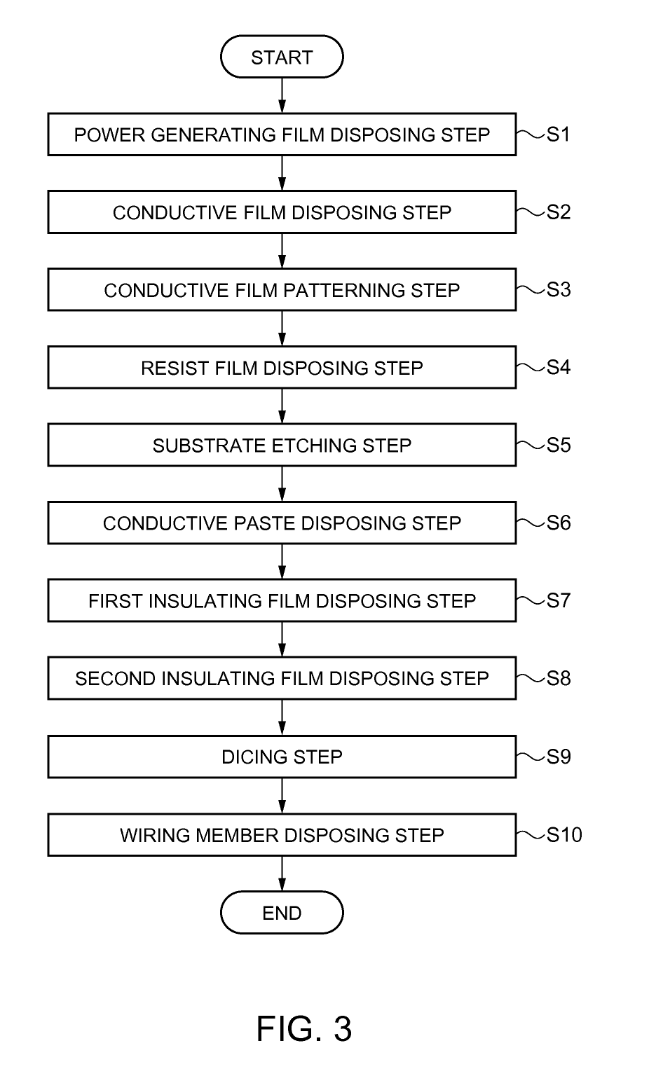

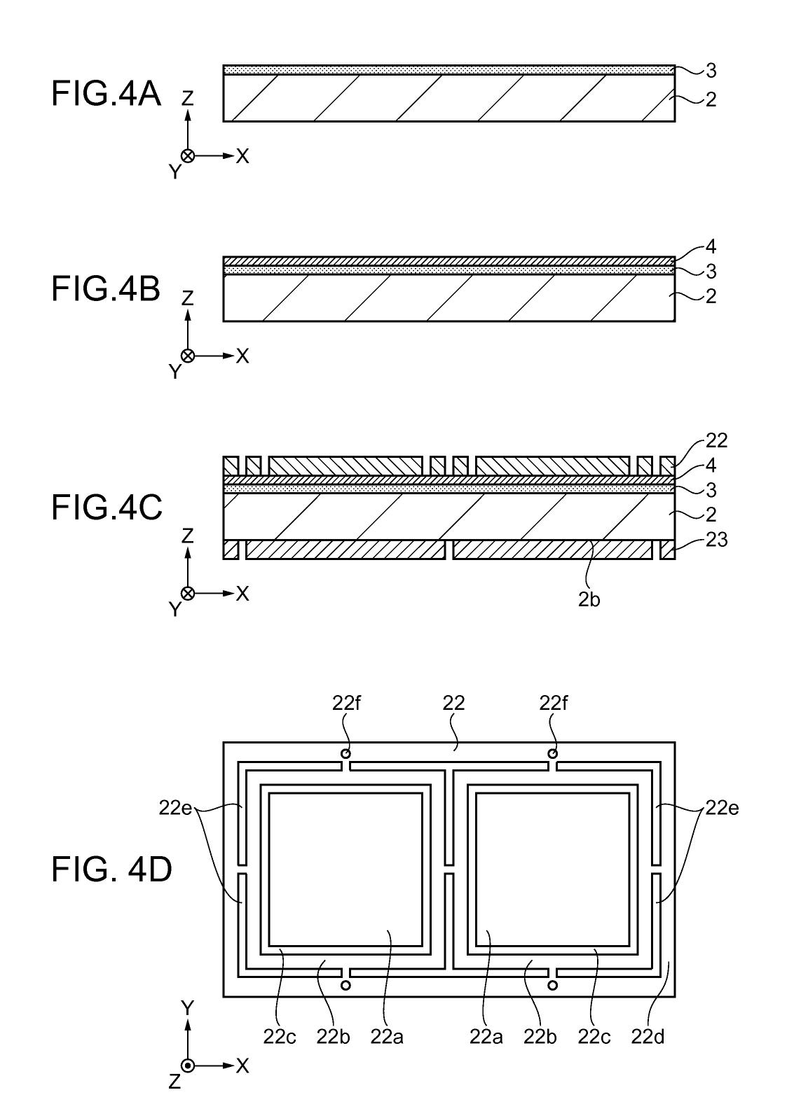

Next, the manufacturing method of the solar cell 1 described above will be described with reference to FIGS. 3 to 9C. FIG. 3 is a flowchart of a manufacturing method of a solar cell, and FIGS. 4A to 9D are schematic views for illustrating the manufacturing method of a solar cell. In the flowchart of FIG. 3, Step S1 corresponds to a power generating film disposing step. This step is a step of disposing the power generating film 3 on the substrate 2. Next, the process proceeds to Step S2. Step S2 corresponds to a conductive film disposing step. This step is a step of disposing the transparent conductive film 4 on the power generating film 3. Next, the process proceeds to Step S3. Step S3 corresponds to a conductive film patterning step. This step is a step of patterning the transparent conductive film 4 into a predetermined shape. Next, the process proceeds to Step S4. Step S4 corresponds to a resist film disposing step. This step is a step of patterning the resist film into a predetermined shape by disposing a resist film on both surfaces of the substrate 2. Next, the process proceeds to Step S5.

Step S5 corresponds to a substrate etching step. This step is a step of etching the substrate 2 by using the resist film as a mask. Next, the process proceeds to Step S6. Step S6 corresponds to a conductive paste disposing step. This step is a step of disposing the conductive paste 6 on the transparent conductive film 4 in the cut-out portion 5a. Next, the process proceeds to Step S7. Step S7 corresponds to a first insulating film disposing step. This step is a step of disposing the first insulating film 5 on the transparent conductive film 4. Next, the process proceeds to Step S8. Step S8 corresponds to a second insulating film disposing step. This step is a step of disposing the second insulating film 9 on the substrate 2. Next, the process proceeds to Step S9. Step S9 corresponds to a dicing step. This step is a step of separating and dicing the substrate 2. Next, the process proceeds to Step S10. Step S10 corresponds to a wiring member disposing step. This step is a step of disposing the wiring member 8 when the conductive paste 6 is disposed. The manufacturing process of the solar cell 1 ends through the steps described above.

Next, the manufacturing method will be described in detail with reference to FIGS. 4A to 9C by being associated with the steps illustrated in FIG. 3.

FIG. 4A is a diagram corresponding to the power generating film disposing step of Step S1. As illustrated in FIG. 4A, the power generating film 3 is disposed on the substrate 2. First, the aluminum layer 14 is formed on the substrate 2 by using aluminum. Concavities and convexities are formed in the surface of the aluminum layer 14 by adjusting film forming conditions. Next, the zinc oxide layer 15 is formed on the aluminum layer 14.

Next, an amorphous silicon film doped with germanium is formed on the zinc oxide layer 15. Accordingly, a first amorphous silicon germanium layer 17 is formed. Further, an amorphous silicon film doped with germanium is formed on the first amorphous silicon germanium layer 17. Accordingly, a second amorphous silicon germanium layer 18 is formed. When the second amorphous silicon germanium layer 18 is formed, the doping amount of germanium is less than that of the first amorphous silicon germanium layer 17.

Next, an amorphous silicon film is formed on the second amorphous silicon germanium layer 18, and thus an amorphous silicon layer 21 is formed. As described above, the power generating film 3 is formed. The film of each layer is able to be manufactured by using a chemical vapor growth method or a deposition method, a physical vapor growth method such as a sputtering method, or the like.

FIG. 4B is a diagram corresponding to the conductive film disposing step of Step S2. As illustrated in FIG. 4B, in Step S2, the transparent conductive film 4 is disposed on the power generating film 3. The transparent conductive film 4 is formed of ITO, and an ITO film is formed on the power generating film 3 in an overlapping manner. The ITO film is able to be manufactured by using a chemical vapor growth method or a deposition method, a physical vapor growth method such as a sputtering method, or the like.

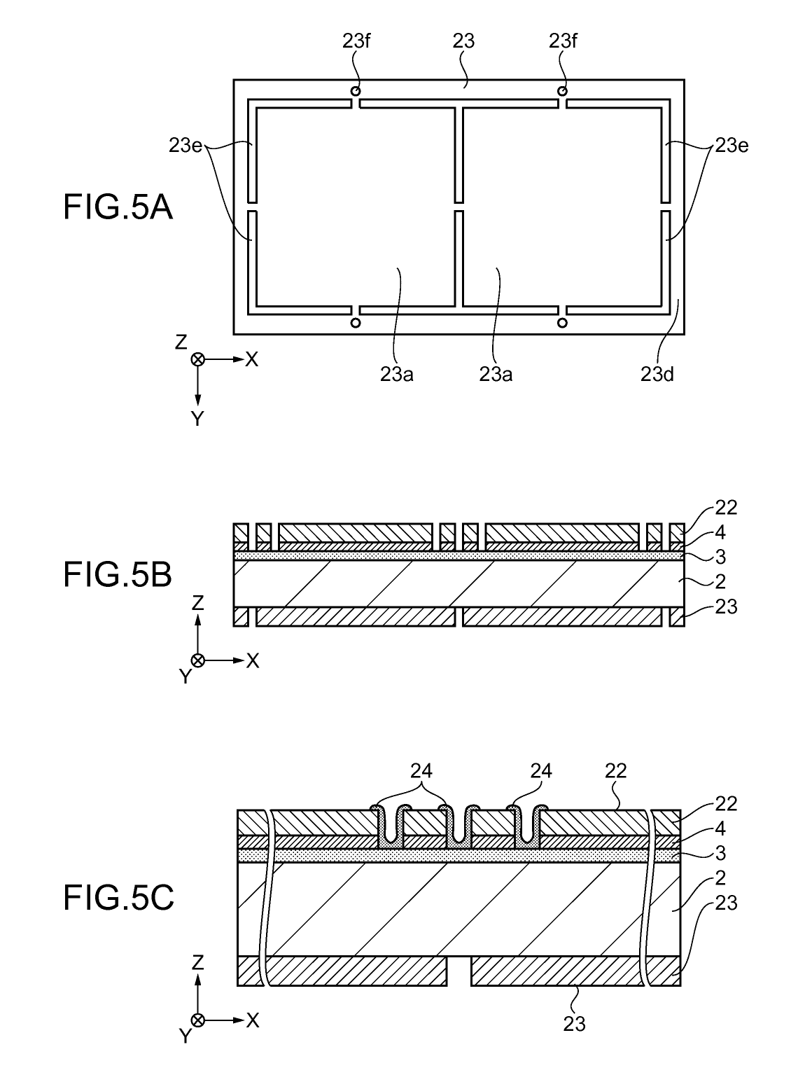

FIGS. 4C to 5B are diagrams corresponding to the conductive film patterning step of Step S3. As illustrated in FIG. 4C, a first front resist film 22 as a first resist film is disposed on the transparent conductive film 4, and a first back resist film 23 as the first resist film is disposed on the second surface 2b of the substrate 2. The first front resist film 22 and the first back resist film 23 are formed of the same resist material, and are able to use a photosensitive resin material. A disposing method of the first front resist film 22 and the first back resist film 23 is not particularly limited. In this embodiment, for example, the first front resist film 22 and the first back resist film 23 are attached to the substrate 2 by using a dry film resist laminate. Next, the first front resist film 22 and the first back resist film 23 are exposed together on the both surfaces. Accordingly, the relative position of the pattern of the first front resist film 22 and the first back resist film 23 is able to be formed with high position accuracy. Next, the first front resist film 22 and the first back resist film 23 is developed by using a developing solution for a photosensitive resin.

FIG. 4D illustrates the pattern of the first front resist film 22. An effective region pattern 22a, an ineffective region pattern 22b, and a groove portion pattern 22c are formed on the first front resist film 22. The effective region pattern 22a corresponds to the effective region 4a of the transparent conductive film 4, and the ineffective region pattern 22b corresponds to the ineffective region 4b of the transparent conductive film 4. The groove portion pattern 22c corresponds to the groove portion 4c. In addition, a front separating pattern 22e separating the front frame pattern 22d from the ineffective region pattern 22b is formed on the first front resist film 22 in addition to the front frame pattern 22d positioned on an outer circumference. Further, a front positioning pattern 22f which is a mark for positioning is formed on the first front resist film 22.

FIG. 5A illustrates the pattern of the first back resist film 23. A bottom surface pattern 23a defining the planar shape of the substrate 2 is formed on the first back resist film 23. Further, a back separating pattern 23e having the same shape as that of the front separating pattern 22e is formed on the first back resist film 23 in a portion facing the front separating pattern 22e. Further, a back positioning pattern 23f having the same shape as that of the front positioning pattern 22f is formed on the first back resist film 23 in a portion facing the front positioning pattern 22f. Further, a back frame pattern 23d having the same shape as that of the front frame pattern 22d is formed on the first back resist film 23 in a portion facing the front frame pattern 22d.

Next, as illustrated in FIG. 5B, the transparent conductive film 4 is etched. When the transparent conductive film 4 is formed of ITO or IGO, the transparent conductive film 4 is etched by using an oxalic acid-based etching liquid. Furthermore, when the second surface 2b of the substrate 2 is corroded by an etching liquid for the transparent conductive film 4, a protective film may be attached to the second surface 2b. Then, the protective film is removed after the etching.

FIG. 5C is a diagram corresponding to the resist film disposing step of Step S4. In Step S4, the groove portion pattern 22c, the front separating pattern 22e, and the front positioning pattern 22f which are formed on the first front resist film 22 are covered with the second resist film 24. Accordingly, the second resist film is disposed by covering a side surface of the transparent conductive film 4. Accordingly, in the substrate etching step of Step S5, the substrate 2 is etched such that the transparent conductive film 4 is covered with the first front resist film 22 and the second resist film 24. As a result thereof, it is possible to prevent the transparent conductive film 4 from being corroded by the etching liquid.

The second resist film 24 is not particularly limited insofar as the second resist film 24 has resistance with respect to an aqueous ferric chloride solution, and various resin materials are able to be used in the second resist film 24. A non-independent resist film is able to be used in the second resist film 24. A disposing method of the second resist film 24 is not particularly limited, and in this embodiment, for example, an electrodeposition method is used in the disposing method of the second resist film 24.

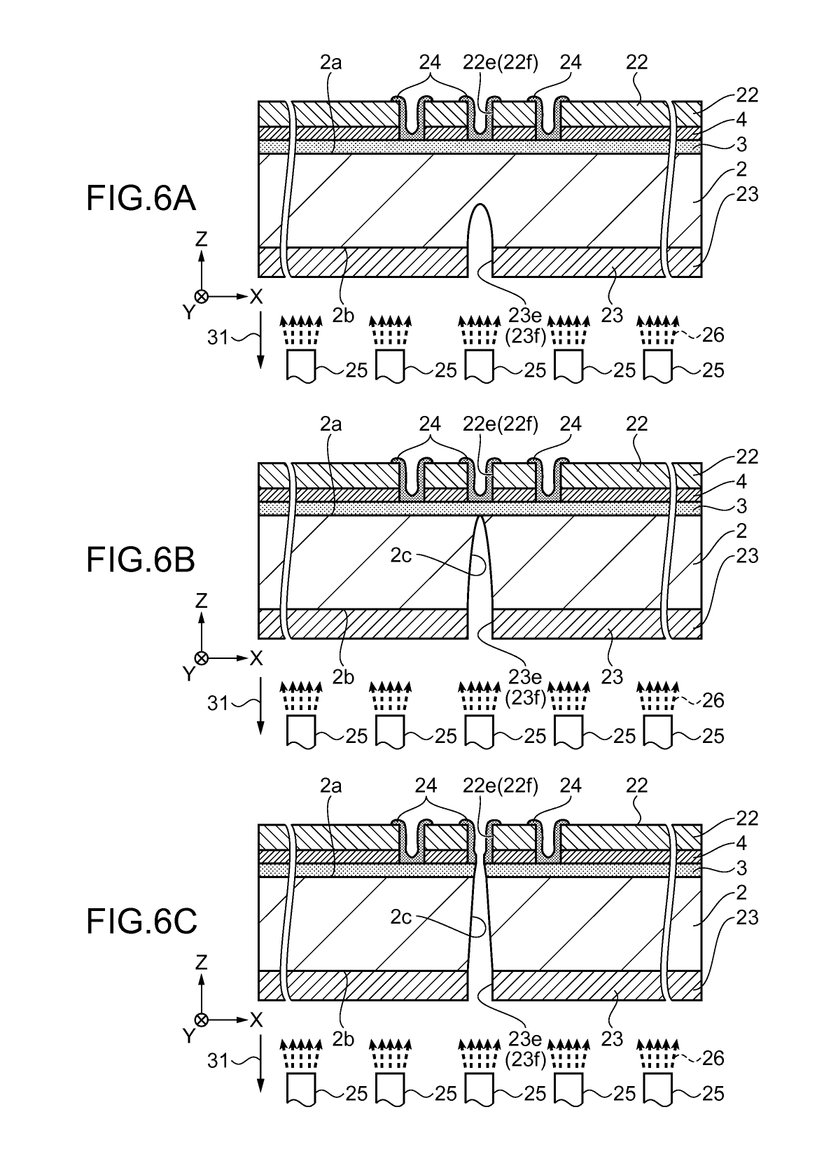

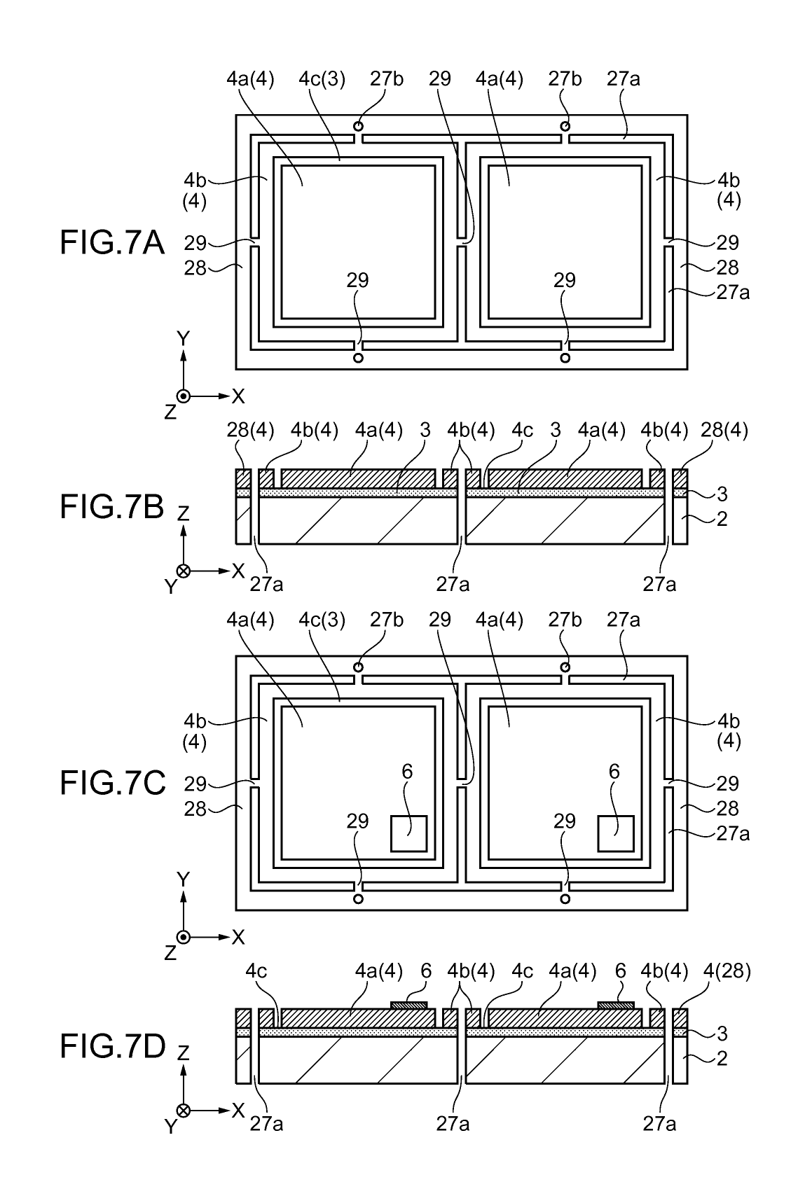

FIGS. 6A to 7B are diagrams corresponding to the substrate etching step of Step S5. As illustrated in FIG. 6A, etching liquid 26 is sprayed onto the second surface 2b side of the substrate 2 from a nozzle 25. The substrate 2 is formed of stainless steel, and thus an aqueous ferric chloride solution is used in the etching liquid 26. The etching liquid 26 is sprayed while the substrate 2 is moved or oscillated in an X direction, and thus the etching liquid 26 is able to be uniformly sprayed onto the second surface 2b. The first surface 2a side of the substrate 2 is covered with the first front resist film 22 and the second resist film 24, and thus the transparent conductive film 4 is prevented from being corroded by the etching liquid 26.

The second surface 2b is directed towards a gravitational acceleration direction 31, and the etching liquid 26 is sprayed thereto. The etching liquid 26 which has reached the second surface 2b reacts with the substrate 2, and thus includes the material of the substrate 2. Then, the etching liquid 26 positioned on the second surface 2b is separated from the second surface 2b due to the action of a gravitational force. Accordingly, in the second surface 2b of the substrate 2, the etching liquid 26 including the material of the substrate 2 is removed and at the same time the etching liquid 26 excluding the material of the substrate 2 is supplied. As a result thereof, it is possible to efficiently etch the substrate 2.

The second surface 2b is masked by the first back resist film 23, and thus the substrate 2 is etched into the shape of the back separating pattern 23e and the back positioning pattern 23f.

As illustrated in FIG. 6B, the etching of the substrate 2 progresses due to the etching liquid 26. Then, a hole 2c formed in the substrate 2 by the etching becomes deeper, and thus reaches the power generating film 3.

As illustrated in FIG. 6C, the etching of the substrate 2 further progresses due to the etching liquid 26. The power generating film 3 and the second resist film 24 are thin films, and thus the power generating film 3 and the second resist film 24 are broken and removed in the hole 2c due to a water pressure of the etching liquid 26. Then, the hole 2c is a through hole penetrating the first surface 2a and the second surface 2b. In the hole 2c, the etching progresses from the second surface 2b side, and thus the substrate has a sectional shape in which the side surface of the substrate 2 is inclined with respect to the first surface 2a, and the first surface 2a protrudes with respect to the second surface 2b.

A side surface of the hole 2c becomes the side surface of the substrate 2 in the solar cell 1. Accordingly, the solar cell 1 has a sectional shape in which the side surface of the substrate 2 is inclined with respect to the first surface 2a, and the first surface 2a protrudes with respect to the second surface 2b.

As illustrated in FIGS. 7A and 7B, the first front resist film 22, the first back resist film 23, and the second resist film 24 are peeled off from the substrate 2. In a portion where the front separating pattern 22e and the back separating pattern 23e are positioned, a separating hole 27a is formed. In a portion where the front positioning pattern 22f and the back positioning pattern 23f are positioned, a positioning hole 27b is formed.

A portion where the front frame pattern 22d and the back frame pattern 23d are positioned is a frame body 28. The frame body 28 and the ineffective region 4b are connected by a connection portion 29. In the drawings, two disposed ineffective regions 4b are also connected by the connection portion 29. Accordingly, four connection portions 29 are disposed on the respective ineffective regions 4b.

FIGS. 7C and 7D are diagrams corresponding to the conductive paste disposing step of Step S6. As illustrated in FIGS. 7C and 7D, in Step S6, the conductive paste 6 is disposed on one corner of the effective region 4a. The conductive paste 6 is able to be disposed by using various printing methods, and the printing method is not particularly limited. In this embodiment, for example, the conductive paste 6 is disposed by using a screen printing method. Next, the conductive paste 6 is heated and dried, and thus is solidified. A heating temperature and a drying time are not particularly limited, and in this embodiment, for example, the heating temperature is approximately 150° C., and the drying time is approximately 30 minutes.

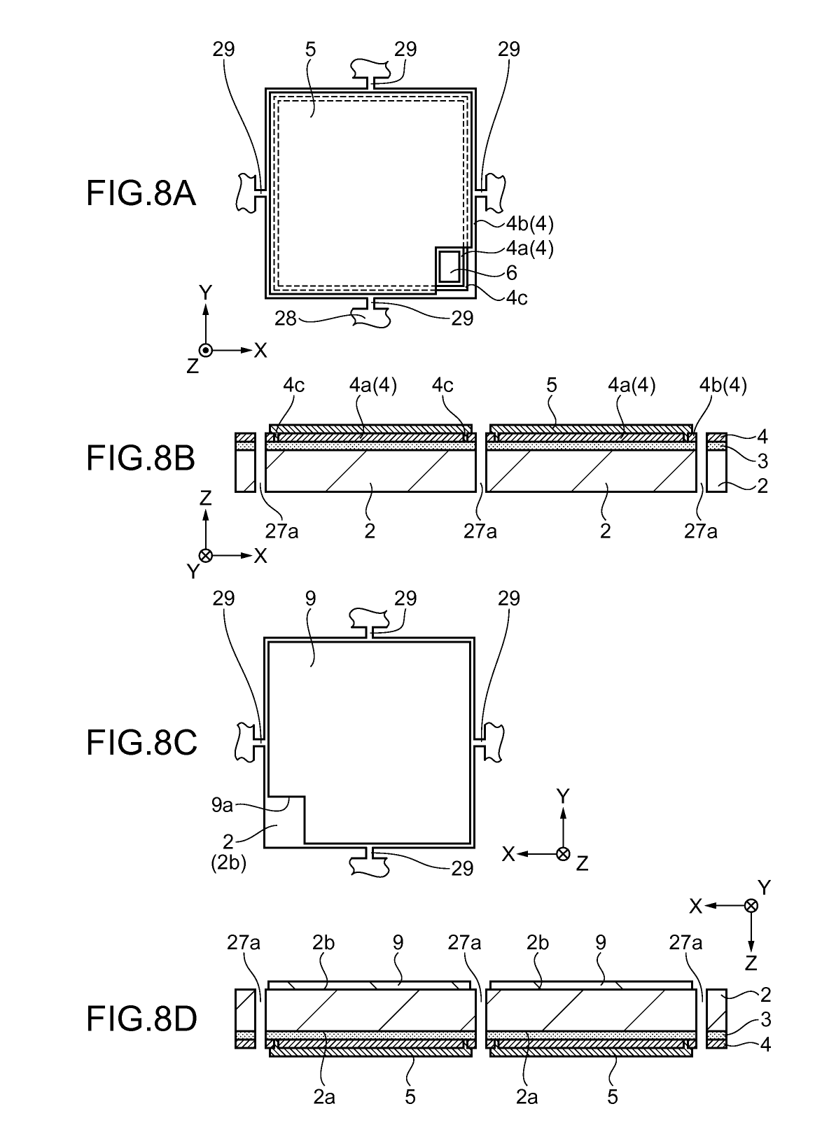

FIGS. 8A and 8B are diagrams corresponding to the first insulating film disposing step of Step S7. As illustrated in FIGS. 8A and 8B, in Step S7, the first insulating film 5 is disposed on the transparent conductive film 4. The first insulating film 5 is disposed in order to cover the effective region 4a by exposing the conductive paste 6. The material of the first insulating film 5 is able to be disposed by using various printing methods, and the printing method is not particularly limited. In this embodiment, for example, the material of the first insulating film 5 is disposed by using a screen printing method. The material of the first insulating film 5 is heated and dried, and thus is solidified. A heating temperature and a drying time are not particularly limited, and in this embodiment, for example, the heating temperature is approximately 150° C., and the drying time is approximately 30 minutes.

FIGS. 8C and 8D are diagrams corresponding to the second insulating film disposing step of Step S8. As illustrated in FIGS. 8C and 8D, in Step S8, the second insulating film 9 is disposed on the second surface 2b of the substrate 2. In the second insulating film 9, a portion facing the conductive paste 6 is cut out, and thus becomes a cut-out portion 9a. In the cut-out portion 9a, the substrate 2 is used as a contact point of a (−) electrode. The second insulating film 9 is disposed in order to cover the second surface 2b of the substrate 2 other than the cut-out portion 9a.

The second insulating film 9 is a polyester film onto which an adhesive material is applied. A surface onto which the adhesive material is applied is directed towards the substrate 2, and the second insulating film 9 is disposed on the substrate 2. The second insulating film 9 is adhered to the substrate 2 by pressing the second insulating film 9. The adhesive material of the second insulating film 9 may be adhered by natural drying or by heating and drying.

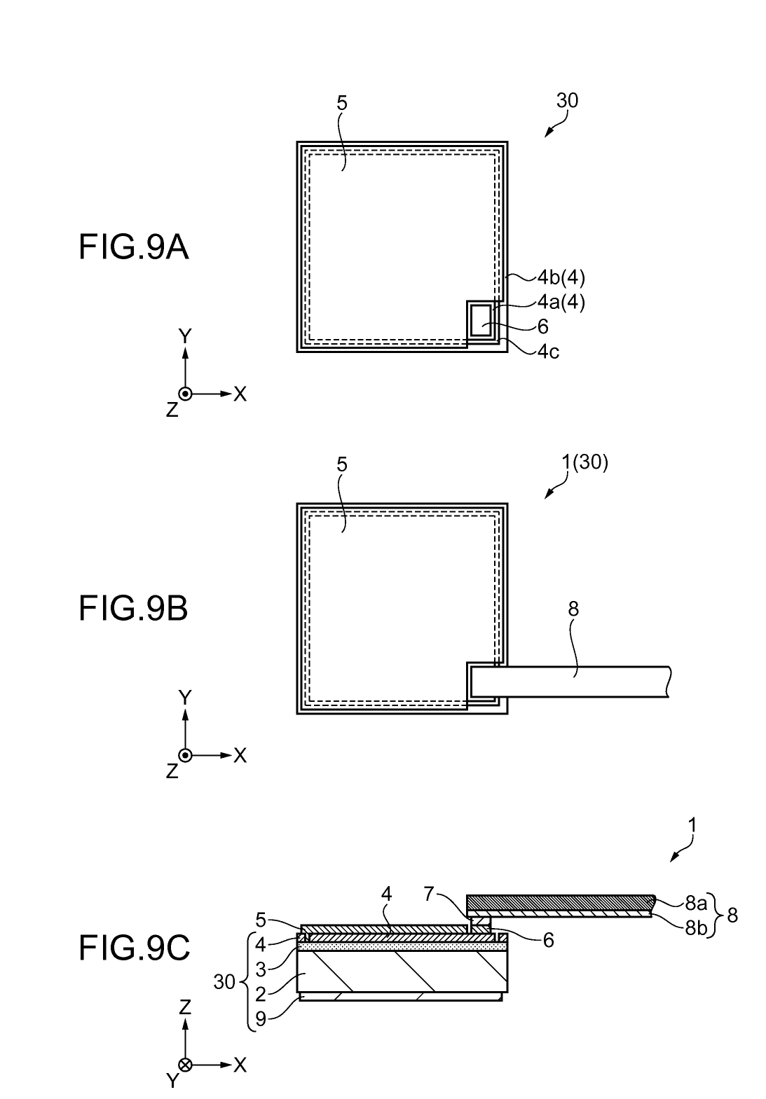

FIG. 9A is a diagram corresponding to the dicing step of Step S9. As illustrated in FIG. 9A, in Step S9, the connection portion 29 is cut, and a solar cell 30 is separated from the frame body 28. A cutting method of the connection portion 29 is not particularly limited, and in this embodiment, for example, a vibration cutting machine is used in the cutting method. Metal fatigue is applied to the connection portion 29 due to vibration, and thus the connection portion 29 is able to be easily cut.

FIGS. 9B and 9C are diagrams corresponding to the wiring member disposing step of Step S10. As illustrated in FIGS. 9B and 9C, in Step S10, the wiring member 8 is disposed on the solar cell 30. First, the anisotropic conductive film 7 is adhered to the metal film 8b of the wiring member 8. In this adhesion, for example, a conductive adhesive material is able to be used.

Next, the anisotropic conductive film 7 is heated while the anisotropic conductive film 7 is disposed on the conductive paste 6 in an overlapping manner and substrate 2 and the wiring member 8 are pressed. A thermosetting adhesive material is included in the anisotropic conductive film 7, and thus it is possible to adhere the wiring member 8 to the solar cell 30. The solar cell 1 is completed through the steps described above.

As described above, according to this embodiment, the following effects are obtained.

(1) According to this embodiment, the etching liquid 26 is sprayed onto the substrate 2 from the second surface 2b side by using the first back resist film 23 as a mask, and thus the substrate 2 is formed into a predetermined shape. In a method of spraying the etching liquid 26 onto the substrate 2 from the both surfaces of the first surface 2a and the second surface 2b, first, the power generating film 3 is patterned into a predetermined shape, and then, the resist film is disposed on the second surface 2b and is patterned. Subsequently, the etching liquid 26 is sprayed onto the substrate 2 from the both surfaces. It is preferable that the pattern of the power generating film 3 is identical to the pattern of the first back resist film 23.

However, when there is a position shift in the patterning, the shape accuracy of the substrate 2 decreases after the etching. In addition, the patterning is performed twice. Compared to this method, in the method of spraying the etching liquid 26 only from the second surface 2b, the patterning is performed once, and thus there is no position shift in the patterning. In addition, the substrate 2 and the power generating film 3 are etched once, and thus it is possible to form the solar cell 1 with high productivity compared to the method where the etching is performed twice.

(2) According to this embodiment, the transparent conductive film 4 is patterned before etching the substrate 2. Then, the second resist film 24 is disposed by covering the side surface of the transparent conductive film 4. Accordingly, the substrate 2 is etched such that the transparent conductive film 4 is covered with the first front resist film 22 and the second resist film 24. As a result thereof, it is possible to prevent the transparent conductive film 4 from being corroded by the etching liquid 26.

(3) According to this embodiment, the second surface 2b of the substrate 2 is directed towards the gravitational acceleration direction 31, and the etching liquid 26 is sprayed onto the second surface 2b. The etching liquid 26 which has reached the second surface 2b reacts with the substrate 2, and thus includes the material of the substrate 2. Then, the etching liquid 26 positioned on the second surface 2b is separated from the second surface 2b due to the action of a gravitational force. Accordingly, in the second surface 2b of the substrate 2, the etching liquid 26 including the material of the substrate 2 is removed and at the same time the etching liquid 26 excluding the material of the substrate 2 is supplied. As a result thereof, it is possible to efficiently etch the substrate 2.

(4) According to this embodiment, the side surface of the substrate 2 is inclined with respect to the first surface 2a. Then, the first surface 2a protrudes with respect to the second surface 2b. The side surface of the substrate 2 is inclined with respect to the first surface 2a, and thus the substrate 2 is formed by spraying the etching liquid 26 thereto. Then, the first surface 2a on which the power generating film 3 is disposed protrudes from the second surface 2b, and thus the resist film is disposed on the second surface 2b, and the etching liquid 26 is sprayed from the second surface 2b side. At this time, the etching liquid 26 is sprayed only from the second surface 2b. Accordingly, the solar cell 1 of this embodiment is patterned once, and thus has no position shift in the patterning. In addition, the etching is performed once, and thus it is possible to manufacture the solar cell 1 with high productivity compared to the method where the etching is performed twice.

(5) According to this embodiment, the solar cell 1 is formed by the etching. In a case of performing blanking in a press metal die, shape accuracy decreases when the size of the solar cell 1 increases. In the etching, the shape accuracy is determined according to the accuracy of an exposure device, and thus it is possible to form a shape having high accuracy compared to the blanking.

### Second Embodiment

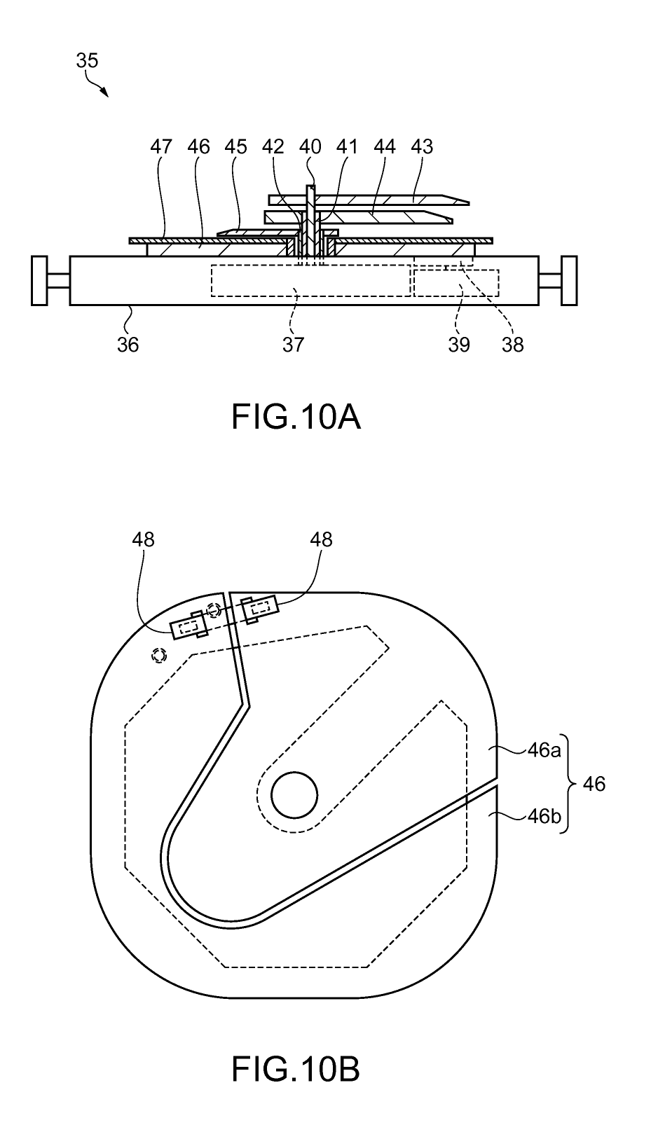

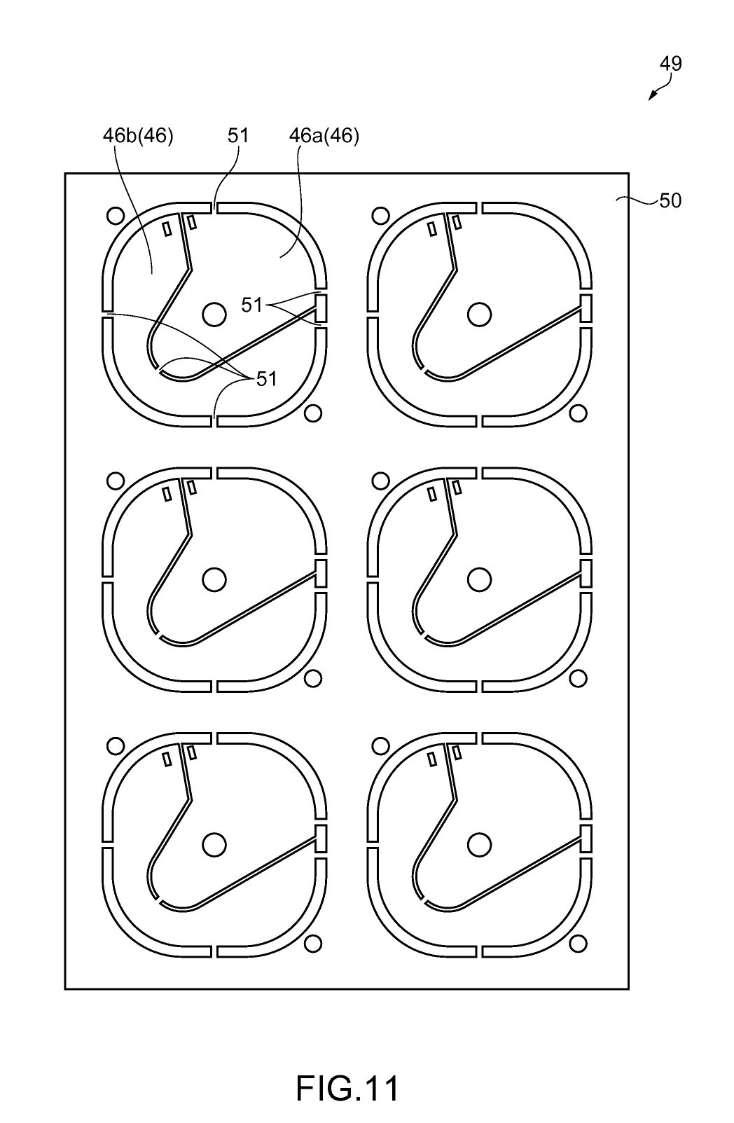

Next, one embodiment of a solar cell will be described with reference to FIGS. 10A to 11. FIG. 10A is a schematic side view illustrating a structure of a timepiece, and FIG. 10B is a schematic plan view illustrating a structure of a solar cell. FIGS. 10A and 10B are diagrams in which the outer package of the timepiece is not illustrated. The timepiece of this embodiment includes a solar cell having the same structure as that of the first embodiment. Furthermore, the description of the same parts as those of the first embodiment will be omitted.

That is, in this embodiment, as illustrated in FIGS. 10A and 10B, the timepiece 35 as an electronic device includes a movement 36, and a train wheel 37, a driving circuit 38, a power supply unit 39, and the like are disposed on the movement 36. The movement 36 indicates a portion excluding the outer package, hands, and the like in the timepiece 35. The train wheel 37 is configured of a plurality of gears, and each of the gears is rotated at different number of rotations. A second hand shaft 40, a minute hand shaft 41, and an hour hand shaft 42 protrude from the train wheel 37. A second hand 43 is disposed on the second hand shaft 40, and a minute hand 44 is disposed on the minute hand shaft 41. An hour hand 45 is disposed on the hour hand shaft 42.

A solar cell 46 and a dial plate 47 are disposed on the movement 36 on the hour hand 45 side of the movement 36 in an overlapping manner. A graduation showing hours, minutes, and seconds is disposed on the dial plate 47. The dial plate 47 is configured of a light transmissive material, and the solar cell 46 is irradiated with light with which the timepiece 35 is irradiated. Then, the solar cell 46 receives the light and generates power. The solar cell 46 is connected to the driving circuit 38 by wiring (not illustrated).

The electric power generated by the solar cell 46 passes through the driving circuit 38 and energizes the power supply unit 39. The power supply unit 39 includes a capacitor, and the power supply unit 39 accumulates the electric power generated by the solar cell 46. A motor (not illustrated) is disposed on the driving circuit 38, and the driving circuit 38 drives the motor. At this time, the driving circuit 38 uses the electric power accumulated in the power supply unit 39. The gear in the train wheel 37 is rotated by the motor, and the second hand shaft 40, the minute hand shaft 41, and the hour hand shaft 42 are rotated. As a result thereof, the second hand 43, the minute hand 44, and the hour hand 45 are rotated.

As illustrated in FIG. 10B, the solar cell 46 includes a first solar cell 46a and a second solar cell 46b, and the first solar cell 46a and the second solar cell 46b are connected in series by the wiring member 48.

The solar cell 46 has the same structure as that of the solar cell 1 of the first embodiment. The solar cell 46 includes the substrate 2, and the power generating film 3 is disposed on the first surface 2a of the substrate 2. The side surface of the substrate 2 is inclined with respect to the first surface 2a, and the first surface 2a protrudes with respect to the second surface 2b. That is, the solar cell 46 is formed by the etching, and is formed by spraying the etching liquid 26 from the second surface 2b side.

FIG. 11 is a schematic plan view of a solar cell-attached substrate, and is a diagram for illustrating the substrate etching step of Step S5. As illustrated in FIG. 11, a solar cell-attached substrate 49 includes a frame body 50. six first solar cells 46a and second solar cells 46b are formed on the solar cell 30. The first solar cell 46a is connected to the frame body 50 by a connection portion 51, and the second solar cell 46b is also connected to the frame body 50 by the connection portion 51. The first solar cell 46a and the second solar cell 46b are connected by the connection portion 51.

The solar cell-attached substrate 49 is etched by spraying the etching liquid 26 onto a surface on a side where the power generating film 3 is not disposed as with the first embodiment from the nozzle 25. That is, in the solar cell 46, the shape of the power generating film 3 and the solar cell-attached substrate 49 is formed by performing the etching once. Accordingly, the solar cell 46 is a cell which is formed with high shape accuracy and high productivity. As a result thereof, the timepiece 35 may be an electronic device including the solar cell which is formed with high shape accuracy and high productivity.

Furthermore, this embodiment is not limited to the embodiments described above, and is able to be variously modified or improved by a person with ordinary skill in the art within the technical ideas of the invention. Modification examples are as follows.

### Modification Example 1

In the first embodiment, in the resist film disposing step of Step S4, the groove portion pattern 22c, the front separating pattern 22e, and the front positioning pattern 22f of the first front resist film 22 are covered with the second resist film 24. Instead of this method, the first front resist film 22 may be peeled off, and a resist film having the pattern of the front separating pattern 22e and the front positioning pattern 22f may be disposed on the transparent conductive film 4. Then, a portion corresponding to the groove portion pattern 22c is covered with the resist film. Then, the etching liquid 26 may be sprayed onto the second surface 2b side from the nozzle 25. In this method, it is possible to form the solar cell 1 with high shape accuracy.

### Modification Example 2

In the first embodiment, the solar cell 1 is formed of the rectangular substrate 2. The substrate 2 may be an elongated coil material. It is possible to efficiently supply the substrate 2 to a manufacturing device. Furthermore, the coil material is also referred to as a ribbon material or a hoop material.

### Modification Example 3

In the first embodiment, the semiconductor layer 16 is the multi-junction type power generating layer having a three-layer structure. The semiconductor layer 16 may be a layer generating power by light, and various pn junctions and pin junctions may be applied to the semiconductor layer 16.

### Modification Example 4

In the second embodiment, an example of the timepiece 35 including the solar cell 46 is described. In all electronic devices including the solar cell, a solar cell which is formed by spraying the etching liquid 26 from the second surface 2b side of the substrate 2 is able to be disposed. As a result thereof, the electronic device is able to include the solar cell which is formed with high shape accuracy and high productivity. For example, a solar cell which is manufactured by the same manufacturing method as that of the solar cell 1 described above is able to be disposed on the electronic device such as a mobile phone, Pedometer (registered trademark), a radio, a television, a digital camera, a camcorder, and a temperature indicator.

What is claimed is:

1. A manufacturing method of a solar cell, comprising:
disposing a power generating film having a photoelectric conversion function on a first surface of a substrate;
disposing a first resist film on the first surface side and a second surface on a side opposite to the first surface;
patterning the first resist film into a predetermined shape; and
forming the substrate into a predetermined shape by spraying an etching liquid onto the substrate from the second surface side.

2. The manufacturing method of a solar cell according to claim 1,
wherein the first resist film is patterned into a shape which is different from that of the first surface side and the second surface.

3. The manufacturing method of a solar cell according to claim 1, further comprising:
disposing a transparent conductive film on the power generating film in an overlapping manner before the first resist film is disposed;
disposing the first resist film on the transparent conductive film;
etching the transparent conductive film after the first resist film is patterned; and
disposing a second resist film by covering a side surface of the transparent conductive film.

4. The manufacturing method of a solar cell according to claim 1,
wherein the second surface is directed towards a gravitational acceleration direction at the time of spraying the etching liquid onto the substrate.

5. A solar cell,
wherein a substrate includes a first surface and a second surface facing the first surface, and a power generating film having a photoelectric conversion function is disposed on the first surface,
a side surface of the substrate is inclined with respect to the first surface, and
the first surface protrudes with respect to the second surface.

6. An electronic device comprising a solar cell,
wherein the solar cell is the solar cell according to claim 5.

7. The electronic device according to claim 6,
wherein the electronic device is a timepiece.
